(19) United States
(12) Patent Application Publication
(10) Pub. No.: US 2026/0107425 A1
(43) Pub. Date: Apr. 16, 2026

(54) ELECTROMAGNETIC WAVE SHIELDING THERMOPLASTIC COMPOSITION

(71) Applicant: GRAPHENEST S.A., Paradela (PT)

(72) Inventors: Bruno REIS FIGUEIREDO, Oliveira do Bairro (PT); Vitor Emanuel MARQUES ABRANTES, Aveiro (PT); Rui Pedro FONSECA FERREIRA DA SILVA, Macinhata do Vouga (PT); JOÃO NUNO DUARTE RODRIGUES, Braga (PT)

(73) Assignee: GRAPHENEST S.A., Paradela (PT)

(21) Appl. No.: 19/116,778

(22) PCT Filed: Sep. 29, 2023
(86) PCT No.: PCT/IB2023/059797

§ 371 Date: Mar. 28, 2025

(30) Foreign Application Priority Data
Sep. 29, 2022 (PT) 118227
Mar. 31, 2023 (EP) 23165998.8

(51) Int. Cl. H05K 9/00; C08K 3/04; C08K 3/22; C08K 5/00

(52) U.S. Cl. CPC H05K 9/0083; C08K 3/042; C08K 3/22; C08K 5/0016; C08K 2003/2265; C08K 2201/001; C08K 2201/005

(57) ABSTRACT

The present disclosure relates to an electromagnetic wave shielding thermoplastic composition, comprising: 0.1 to 50 wt. % of graphene; 0.1 to 25 wt. % of a further carbon-based conductive material; 10 to 90 wt. % of a polymer matrix; wherein the weight ratio of graphene to carbon-based conductive material (wt/wt) is 3:1 to 1:1; wherein the further carbon-based conductive material is crystalline or semicrystalline. It also relates to an electromagnetic wave shielding thermoplastic granulate, thermoplastic powder, thermoplastic film, thermoplastic sheet or thermoplastic paste comprising said composition.

### TECHNICAL FIELD

The present disclosure relates to conductive polymers. More specifically, the present disclosure includes highly conductive graphene-filled polymers for radio frequency interference (RFI) and electromagnetic interference (EMI) shielding. The compound can be processed as part of the manufacturing of shielding parts, such as cables or housings.

### BACKGROUND

Human-made and natural electromagnetic interference (EMI) sources can cause temporary disturbances, data loss, and failure of electronic devices, equipment, and systems. These problems create many challenges and are of critical importance to the automotive, aerospace, defence, and medical industries.

EMI has risen immensely due to the exponential density growth of electronics, which may degrade device performance, and adjacent systems and even adversely affect human health. Miniaturisation has further aggravated the EMI issue as mutual interference among the device's components or chip elements can produce localized interference effects. This impelled the development of suitable countermeasures to suppress (or eliminate) EMI effects.

Existing shielding methods that address these issues use brittle, inflexible and heavy systems, as well as rigid enclosures, meshes and foils made from heavy-weight and expensive metals like silver, copper, stainless steel, aluminium, and nickel.

Metals are by far the most common materials for EMI shielding owing to their high electrical conductivity. However, they suffered from problems such as high reflectivity, corrosion susceptibility, weight penalty, high carbon footprint, and uneconomic processing. In this consideration, polymer-based blends and composites have attracted enormous attention due to the unique combination of electrical, thermal, dielectric, magnetic and/or mechanical properties useful for efficient electromagnetic shielding response.

Materials based on multi-layered graphene have attracted much attention due to their unique properties. Recently, several attempts have been made to exploit the fascinating and promising properties of graphene-based nanocomposites, particularly for electrical and electromagnetic shielding applications. The use of this high aspect ratio and conductivity material, provides a suitable solution for high EMI shielding and applications in cables, integrated electronics, sensors, batteries, transistors, and capacitors, among others.

Graphene-based structures have been the focus of several studies because their outstanding electrical properties render thin skin depth, leading to the efficient deterioration of the electromagnetic field caused by absorption loss within the shielding material. In addition, because of its mechanical properties, graphene has been considered a promising candidate as an EMI shield (C. Acquarelli, a Rinaldi, a Tamburrano, G. De Bellis, a G. D. Aloia, and M. S. Sarto, pp. 488493, 2014) as it allows the production of flexible and light systems.

In summary, compared to traditional metal shields, graphene itself is more efficient, lightweight, and flexible, so it has the potential for commercial applications (J. Liang, Y. Wang, Y. Huang, Y. Ma, Z. Liu, and J. Cai, vol. 47, no. 3, pp. 922925, 2008).

Document U.S. Pat. No. 11,071,241 B2 discloses an electromagnetic wave shielding material using graphene, an electromagnetic wave shielding film including the graphene and an electronic or electric device including the electromagnetic wave shielding material or film. More specifically, the document discloses the shielding of electromagnetic waves in a broad frequency band from about 2 GHz to about 18 GHz using graphene produced by, for example, chemical vapour deposition.

Document WO 2014/061048 A2 is related to the formulation and production of nanostructured materials with a base of graphite or graphene, in particular graphene nanoplatelets with controlled morphological and electrical properties, and the use of said GNP as fillers in variable concentrations for producing polymeric matrix nanocomposites with controlled properties of complex dielectric permittivity. More specifically, the document discloses the fabrication, by means of said nanocomposites, of thin panels or coatings with shielding and/or radar-absorbent properties at radiofrequency (X and Ku band, from 8-18 GHz).

Document U.S. Pat. No. 9,174,413 B2 encompasses the description of electromagnetic interference shielding structures and methods of shielding an object from electromagnetic radiation at frequencies greater than 1 megahertz, and it includes providing highly doped graphene sheets around the object to be shielded.

Document CN 104845361 A describes a highly conductive thermoplastic plastic reinforced cooperatively by short carbon fiber and nano highly conductive carbon black/graphene. The document discloses a complex 2-step treatment of the chopped carbon fiber surface previously to its use: 1) a plasma cleaning to remove surface organic matter polluters and non-carbon oxide compounds; and 2) a chemical and physical etching to ensure the presence of carboxyl, carbonyl, and hydroxyl reactive groups.

Document CN 101072493 A relates to a kind of polyvinyl resin film. More specifically, it relates to a polyethylene film for shielding a wideband electromagnetic wave and preparation method thereof. The document discloses an admixture of metal fibers and metal conduction powder. More specifically, the metal fibers are admixtures of polycrystal iron fiber and stainless-steel fiber, while the metal conduction powders include nickel powder, copper powder, iron powder, or aluminium powder. In addition, it also relates to other admixture of metal fibers and carbon fiber. The metal fibers are polycrystal iron fiber or stainless-steel fiber; carbon fibers are nicarbazin fiber or nickel-plated graphite fiber.

Document CN 1772798 A discloses one kind of conductive plastic and its processing method and apparatus. The conductive plastic includes an electro-conductive fiber, a thermoplastic plastic, and a machining assistant. The conductive fiber is arranged in a 3D netted form homogeneously with multiple joining points, and the conductive plastic has high conductivity, high antistatic and electromagnetic shielding effect, and low surface resistance and volumetric resistivity, and may be injected, extruded and molded like common plastic. In addition, the document en compasses the use of several compositions or the mixtures of steel fiber, carbon fiber, metallizing carbon fiber, metallized glass fiber, metallizing boron fibre and metallizing silicon carbide fiber, etc.

Document CN 105694427 B discloses a graphene-based composite material for electromagnetic shielding. Reduced graphene oxide is evenly coated at a foam sponge skeleton surface, rendering a composite with an electrically conductive isotropic skeleton. 1.5 mm thickness produces an electromagnetic shield effectiveness higher than 40 dB. Simultaneously, the material can bear a compressive deformation up to 80% showing good flexibility and elasticity. In addition, the document relates to a material with a density of only 0.05 g/cm³, rendering a specific shielding effectiveness up to 800 dB cm³/g.

The graphene-based composite material can be used in industrial methods and is largely prepared, at a low cost and has as its characteristics the versatility, efficiency, and low density.

The present disclosure presents a lighter solution for electromagnetic shielding and having high conductivity.

These facts are disclosed in order to illustrate the technical problem addressed by the present disclosure.

### GENERAL DESCRIPTION

The present disclosure relates to a graphene-based compound composition for RFI and EMI. Additionally, the present disclosure also offers customized electrical conductivity and wave attenuation levels.

The compound of the present disclosure comprises the following advantages:
up to 75% reduction in weight by replacing heavy metal shielding; excellent conductivity with planar electrical resistance from 0.1 to 500 Ohm/sq; more than 20 dB attenuation within radio and microwave frequency ranges from 3 K Hz to 30 GHz;
more than 50 dB attenuation with microwave frequency ranges from 30 GHz to 300 GHz preferably from 60 GHz to 90 GHz.

The compound composition can be applied as a Radio Frequency Interference and Electromagnetic Interference (RFI & EMI) shielding part of industrial equipment, electronic parts, medical devices, communication devices, office devices, military devices, automotive components, aerospace devices, EMI/RFI shielding enclosures, automobile cables, solar panels, consumer electronics, mobile and flexible electronics, wearable electronics, board-level shielding and patches.

It is also disclosed compositions comprising compounds with a polymeric matrix that can contain additive agents and conductive carbon-based filler comprising at least graphene platelets. The graphene-based compounds are compatible with large-scale production systems and can be further processed by extrusion, injection moulding, thermoforming, or rotational moulding.

The present disclosure relates to an electromagnetic wave shielding thermoplastic composition (weights are in respect of the final composition), comprising:
0.1 to 50 wt. % of graphene as a first carbon-based conductive material;
0.1 to 25 wt. % of a further carbon-based conductive material;
10 to 90 wt. % of a polymer matrix;
wherein the weight ratio of graphene to the further carbon-based conductive material (wt/wt) is 3:1 to 1:1.

In an embodiment for better results, the weight ratio of graphene to the further carbon-based conductive material (wt/wt) is 2.5:1 to 2:1, preferably 2:1. Remarkably, carbon-based conductive material has a very small particle size, as well as a different aspect ratio compared to graphene particles (round-shaped vs. flake-shaped, respectively), and thus the present weight ratios promote the dispersion of such particles at low and high-shear processes and allow to achieve particle percolation, a condition that is important for optimal electrical conductivity.

In an embodiment, the graphene is graphene functionalized with ferromagnetic particles, in particular up to 75 wt. % of the graphene is functionalized with ferromagnetic particles, the weight ratio of graphene to ferromagnetic particles is 2:1 to 1:2. In an embodiment the ferromagnetic particles are iron oxides compounds. In particular up to 50 wt. % of the graphene is functionalized with iron oxide, the weight ratio of graphene to iron oxide is 2:1 to 1:2.

In an embodiment, the composition further comprises ferromagnetic particles as filler, in particular the composition comprising up to 20 wt. % of an additive containing ferromagnetic particles, in particular up to 20 wt. % of ferromagnetic particles.

In an embodiment, the composition further comprises an additive selected from a plasticizer, a compatibilizer, a dispersant, an antioxidant, among others, and combinations thereof.

In an embodiment, the further carbon-based conductive material is crystalline or semicrystalline.

In an embodiment, the further carbon-based conductive material is nanostructured.

In an embodiment, the further carbon-based conductive material is a material comprising carbon-based particles, preferably is a plurality of carbon-based particles, having particle size inferior to 25 nm that might form chain-like agglomerates of particles from 1 to 100 micrometres of length, respectively, this being measured, for example, by scanning electron microscopy and measuring the largest visible size for each particle using ImageJ software.

In an embodiment, the graphene lateral size is from 0.5 to 30 μm.

Measurement of the graphene lateral size can be carried out in a number of ways, namely scanning electron microscopy (SEM), transmission electron microscopy (TEM), among others; in this disclosure the graphene lateral size was measure according to ISO/TS 21356-1:2021.

In an embodiment, the graphene is in the form of platelets or nanoplatelets having a D10, D50 and D90 particle size inferior to 2, 5 and 15 μm, respectively, this being measured, for example, by collecting several images with over 150 individual particles by scanning electron microscopy and measuring the largest visible size for each particle using Image software. Particularly, the graphene is in the form of platelets or nanoplatelets having an average particle lateral size of 3.2±1.6 μm, this being measured by imaging 4698 individual particles by scanning electron microscopy and measuring first the length and then the width (perpendicularly to the length measurement) for each particle using ImageJ software, according to the procedures from ISO/TS 21356-1:2021. Measurement of the graphene size can be carried out in a number of ways, namely scanning electron microscopy (SEM), transmission electron microscopy (TEM), among others; in this disclosure the graphene lateral size was measure according to ISO/TS 21356-1:2021.

In an embodiment, the graphene particle lateral size ranges from 1.5 to 5 μm; preferably 1.6 to 4.5 μm; more preferably 2 to 3.2 μm, measured by scanning electron microscopy.

Graphene size refers to the overall dimensions or extent of a graphene structure in three-dimensional space. It encompasses the length, width, and thickness (or height) of the graphene material.

Graphene lateral size, on the other hand, specifically refers to the two-dimensional dimensions of a graphene sheet or layer.

In an embodiment, the further carbon-based conductive material is selected from the list: natural and synthetic graphite, carbon black, carbon nanotubes, carbon fibers, carbon nano onions, graphene oxide, carbon nanospheres, fullerenes, or mixtures thereof.

In an embodiment, for better results, the further carbon-based conductive material is carbon black. The carbon black is composed of smaller, rounded particles that can fill the spaces between the graphene nanoparticles, promoting a greater number of contact sites between the two materials, which in turn results in the proper electrical percolation for EMI shielding performance. Carbon black typical particle size varies between 13 and 50 nm, or less than 25 nm.

In an embodiment, the amount of graphene is 1 to 30 wt. %, more preferably 5 to 20 wt. %.

In an embodiment, the amount of the further carbon-based conductive material 0.1 to 25 wt. %, preferably 0.3 to 20 wt. %, more preferably 0.5 to 15 wt. %, more preferably 1 to 15 wt. %, more preferably 2 to 15 wt. %.

In an embodiment, the amount of carbon black is 0.1 to 25 wt. %, preferably 0.3 to 20 wt. %, more preferably 0.5 to 15 wt. %, more preferably 1 to 15 wt. %, more preferably 2 to 15 wt. %.

In an embodiment, the polymer matrix is selected from the list: polyvinyl chloride, polyamide, polybutylene terephthalate, cross-linked polyethylene, fluorinated ethylene propylene, polyethylene, polypropylene, polystyrene, acrylonitrile butadiene styrene, polylactic acid, polytetrafluoroethylene, polyethylene terephthalate, polymethylmethacrylate, thermoplastic elastomer, thermoplastic polyurethane, polychlorotrifluoroethylene, polyacrylonitrile, polycarbonate, polydimethylsiloxane, polyethersulfone, polysulfone, polyether ether ketone, polyphenylene sulfide, polyamideimide, and polyetherimide, or mixtures thereof.

In an embodiment, the polymer is polyvinyl chloride or polyamide or polybutylene terephthalate. The graphene and the further carbon-based conductive material can be dispersed in these polar polymers due to the polar oxygen-containing functional groups preventing them from restacking, and thus enhancing their electrically conductive features.

In an embodiment, the polymer matrix is polypropylene, polyvinyl chloride or polyamide or polybutylene terephthalate, or acrylonitrile butadiene styrene or polyethylene.

In an embodiment, for better results, if the polymer matrix is polypropylene than the weight ratio of graphene to the further carbon-based conductive material (wt/wt) is 1:2; if it is polyvinyl chloride than the weight ratio of graphene to the further carbon-based conductive material (wt/wt) is 2:1 ; if it is polyamide than the weight ratio of graphene to the further carbon-based conductive material (wt/wt) is 2:1; if it is polybutylene terephthalate than the weight ratio of graphene to the further carbon-based conductive material (wt/wt) is 2:1; if it is acrylonitrile butadiene styrene than the weight ratio of graphene to the further carbon-based conductive material (wt/wt) is 2:1; if it is polyethylene than the weight ratio of graphene to the further carbon-based conductive material (wt/wt) is 1:1.

In an embodiment, the composition further comprises an additive.

In an embodiment, the amount of additive is 0.1 to 25 wt. %, preferably selected from a plasticizer, dispersant, antioxidant, or combinations thereof. For better results, the additive is a plasticizer and the amount is 0.1 to 25 wt. %. The amount of plasticizer is determined according to the polymer matrix being used and to the required final flexibility. Higher amounts of plasticizer lead to more flexible materials.

In an embodiment, the plasticizer is selected from the list: phthalate esters, trimellitate, aliphatic dibasic acid esters, benzoate esters, polyesters, citrates, epoxidized soybean oil, epoxidized linseed oil (ELO), castor oil, palm oil, starches, sugars, phosphates, chlorinated paraffins, alkyl sulfonic acid esters, or their mixtures thereof, preferably trimellitate.

In an embodiment, the composition further comprising ferromagnetic particle, in particular up to 20 wt. % of ferromagnetic particles.

In an embodiment, the composition is in form of liquid-state; or solid-state. Preferably the liquid state is in situ polymerization and the solid state is compounding and masterbatch. Preferably the composition is in the form of particles, powder or granulate.

In an embodiment, an incident electromagnetic wave with a broad frequency band between 1 kHz to 30 GHz is shielded with an effectiveness higher than 20 dB.

In an embodiment, an incident electromagnetic wave with a broad frequency band between 30 GHz to 300 GHz is shielded with effectiveness higher than 50 dB.

In an embodiment, a planar slab of the composition with a thickness of at least 1 mm guarantees a shielding effectiveness higher than 20 dB and 50 dB, for frequencies between 1 kHz to 30 GHz and for frequencies between 30 GHz and 300 GHz, respectively.

In an embodiment, a planar slab of the composition with a thickness of at least 3 mm guarantees a shielding effectiveness higher than 40 dB and 85 dB for frequencies ranging from 1 kHz to 30 GHz and 30 GHz to 300 GHz, respectively.

The present disclosure also relates to an electromagnetic wave shielding thermoplastic granulate, thermoplastic powder, thermoplastic film, thermoplastic sheet, or thermoplastic paste comprising the composition disclosed in the previous embodiments.

The present disclosure also relates to the use of a composition as electromagnetic wave shielding, wherein said composition comprises:
0.1 to 50 wt. % of graphene as a first carbon-based conductive material;
0.1 to 25 wt. % of a further carbon-based conductive material;
10 to 90 wt. % of a polymer matrix;
wherein the weight ratio of graphene to the further carbon-based conductive material (wt/wt) ranges from 3:1 to 1:0.5; preferably 3:1 to 1:1.

### BRIEF DESCRIPTION OF THE DRAWINGS

The following figures provide preferred embodiments for illustrating the disclosure and should not be seen as limiting the scope of the invention.

FIG. 1: Graphic representation of an embodiment wherein the EMI shielding performance of a 1-millimetre-thick planar slab at low frequencies, from 1 kHz to 3.5 GHz.

FIG. 2: Graphic representation of an embodiment of wherein the EMI shielding performance of a 1-millimetre-thick planar slab at high frequencies, preferably from 60 GHz to 90 GHz.

FIG. 3: Graphic representation of an embodiment wherein the EMI shielding performance of a 3-millimetre-thick slab at low frequencies, from 1 kHz to 3.5 GHz.

FIG. 4: Graphic representation of an embodiment of wherein the EMI shielding performance of a 3-millimetre-thick sample at high frequencies, preferably from 60 GHz to 90 GHz.

FIG. 5: Graphic representation of results of scanning electron microscopy images of the surface (top left and top right figures) and cross-section (bottom left and bottom right figures) of the present description, where it can be seen how the carbon-based material (carbon black) and graphene nanoparticles achieve an agglomerate-free and non-heterogenous cross-section surface at the relevant dimensions for providing the desired electromagnetic shielding.

### DETAILED DESCRIPTION

The present description relates to highly conductive graphene-based polymer compositions suitable for radio frequency shielding (RFI) and electromagnetic interference shielding (EMI) applications, in which in an embodiment, the composition comprises graphene nanoplatelets blended within a polymer matrix. The composition may further comprise other carbon-based fillers. These highly conductive graphene compounds can be used in a plurality of processing methods such as extrusion, injection moulding, thermoforming or rotational moulding.

The present disclosure relates to an electromagnetic wave shielding thermoplastic composition, comprising: 0.1 to 50 wt. % of graphene; 0.1 to 25 wt. % of a further carbon-based conductive material; 10 to 90 wt. % of a polymer matrix; wherein the weight ratio of graphene to carbon-based conductive material (wt/wt) is 3:1 to 1:1 (preferably 3:1 to 2:1); wherein the further carbon-based conductive material is crystalline or semicrystalline. It also relates to an electromagnetic wave shielding thermoplastic granulate, thermoplastic powder, thermoplastic film, thermoplastic sheet or thermoplastic paste comprising said composition.

In an embodiment, the present disclosure can shield electromagnetic waves with an effectiveness higher than 20 dB in a broad frequency band of from 1 kHz to 30 GHz using 1 mm thickness, preferably from 30 MHz to 30 GHz.

In another embodiment, the present disclosure can shield electromagnetic waves with an effectiveness higher than 50 dB in a broad frequency band from 30 GHz to 300 GHz with 1 mm thickness.

Preferred embodiments of the present description will be described in detail with reference to the drawings. However, they are not intended to limit the scope of this application.

In an embodiment, the present disclosure relates to a compound composition comprising graphene nanoplatelets for electromagnetic interference shielding from 1 kHz to 300 GHz frequencies.

In an embodiment, the composition is a graphene-based compound composition for EMI shielding comprising:
graphene nanoplatelets from 0.1 to 50 wt. %, preferably 1 to 30 wt. %; more preferably 5 to 20 wt. %;
other carbon-based materials from 0.1 to 25 wt. % for RFI and EMI shielding, preferably 0.5 to 15 wt. %;
polymer matrix in which the particles are melt blended and dispersed, being the particles the mixture of the graphene nanoplatelets and the carbon-based material, said polymer matrix in an amount from 10 to 90 wt. %; and
optional additives from 0.1 to 25 wt. %, preferably the additives are plasticizers.

In an embodiment, the weight ratio of graphene to the further carbon-based conductive material (wt/wt) is 3:1 to 1:1, preferably is 2.5:1 to 2:1, more preferably 2:1.

In one embodiment the further carbon-based conductive material is selected from the following list: natural and synthetic graphite, carbon black, carbon nanotubes, carbon fibers, carbon nano onions, graphene oxide or carbon nanospheres, fullerenes, or mixtures thereof. Preferably the carbon-based material is carbon black.

In one embodiment, the polymer matrix is selected from the list, but not limited to: polyvinyl chloride (PVC), polyamide (PA), polybutylene terephthalate (PBT), cross-linked polyethylene (XLPE), fluorinated ethylene propylene (FEP), polyethylene (PE), polypropylene (PP), polystyrene (PS), acrylonitrile butadiene styrene (ABS), polylactic acid (PLA), polytetrafluoroethylene (PTFE), polyethylene terephthalate (PET), polyethylethacrylate (PMMA), thermoplastic elastomer (TPE), thermoplastic polyurethane (TPU), polychlorotrifluoroethylene (PCTFE), polyacrylonitrile (PAN), polycarbonate (PC), polydimethylsiloxane (PDMS), polyethersulfone (PES), polysulfone (PSU), polyether ether ketone (PEEK), polyphenylene sulfide (PPS), polyamideimide (PAI), and polyetherimide (PEI) or mixtures thereof.

In one embodiment, the plasticizer is selected from the list to: phthalate esters, aliphatic dibasic acid esters, benzoate esters, polyesters, citrates, epoxidized soybean oil (ESBO), epoxidized linseed oil (ELO), castor oil, palm oil, starches, sugars, phosphates, chlorinated Paraffins, alkyl sulfonic acid esters, and more preferably trimellitate, or their mixture thereof.

In an embodiment, the amount of plasticizer is 0.1 to 25 wt. %.

In an embodiment, the graphene contains below 5 atom. % of oxygen content, which enables simultaneously to achieve a good electrical conductivity and dispersibility of its particles into polar polymer systems. This will increase the overall shielding effectiveness. In an embodiment, the graphene particle thickness is from 1 to 50 nm.

In an embodiment, the electromagnetic wave shielding thermoplastic composition is placed in the form of a planar slab, and the sheet resistance is preferably adjusted for 0.1 to 500 ohm/sq, in order to achieve electric percolation according to the polymer matrix in use whereby a balance between the polymer matrix and electric conductivity is attained.

In one embodiment, the bulk electrical resistivity of the composition is 1×10⁻⁵˜2×10⁻³ ohm·cm.

In an embodiment, the composition is processed via extrusion, mould injection, thermoforming or rotational moulding.

In an embodiment the composition is obtained by hot melt mixing/compounding, or hot melt extrusion, or solvent-melting/compounding, or in situ polymerization mixture. Preferably the composition is obtained by hot melt mixing.

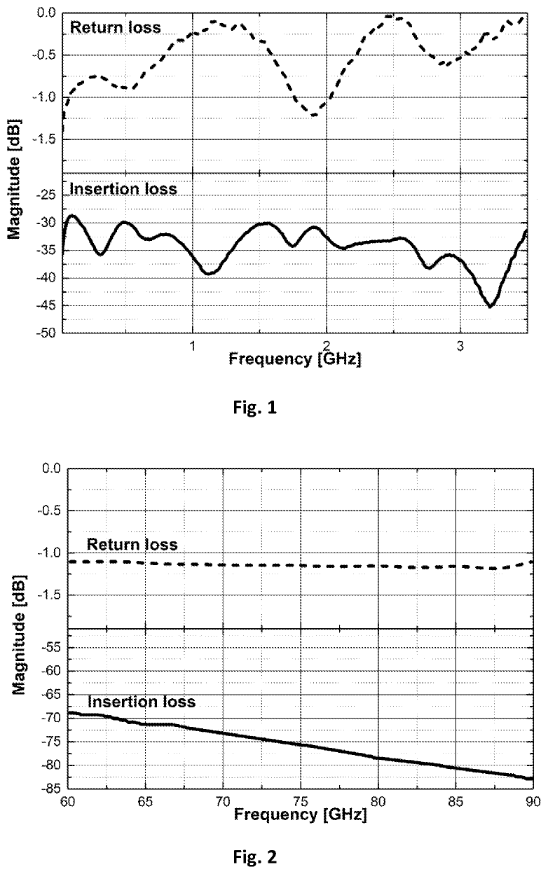

In an embodiment, FIG. 1 shows low-frequency attenuation, from 1 kHz to 4.2 GHz for a 1-millimetre thick planar slab that presents a good attenuation (>30 dB), mostly due to the high absorption capabilities (insertion loss) of the incident EM waves.

In an embodiment, FIG. 2 shows high-frequency attenuation, from 60 to 90 GHZ, for a 1-millimetre-thick planar slab that presents a high attenuation (>50 dB), mostly due to the high absorption capabilities (insertion loss) of the incident EM waves.

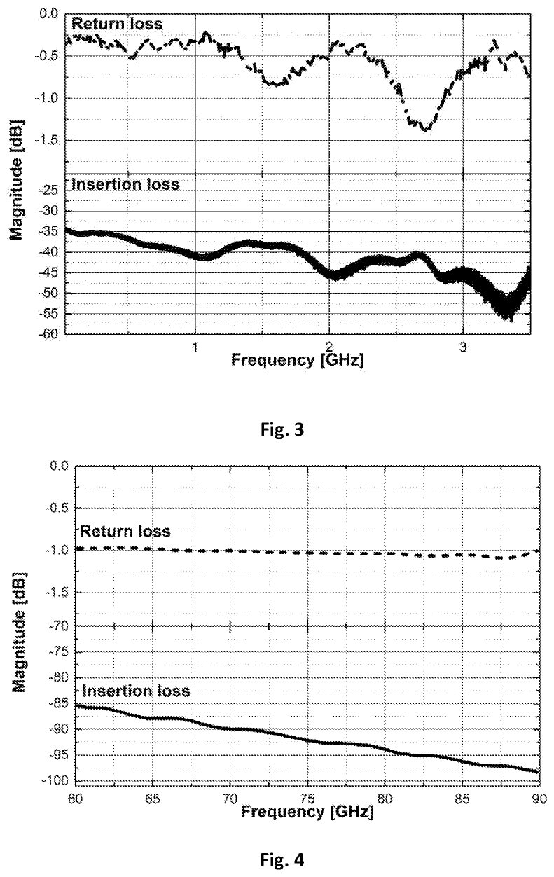

In an embodiment, FIG. 3 shows low-frequency attenuation, from 1 kHz to 4.2 GHz for a 3-millimetre thick planar slab that presents a good attenuation (>40 dB), mostly due to the high absorption capabilities (insertion loss) of the incident EM waves.

In an embodiment, FIG. 4 shows high-frequency attenuation, from 60 to 90 GHz, for a 3-millimetre-thick planar slab that presents a high attenuation (>85 dB), mostly due to the high absorption capabilities (insertion loss) of the incident EM waves.

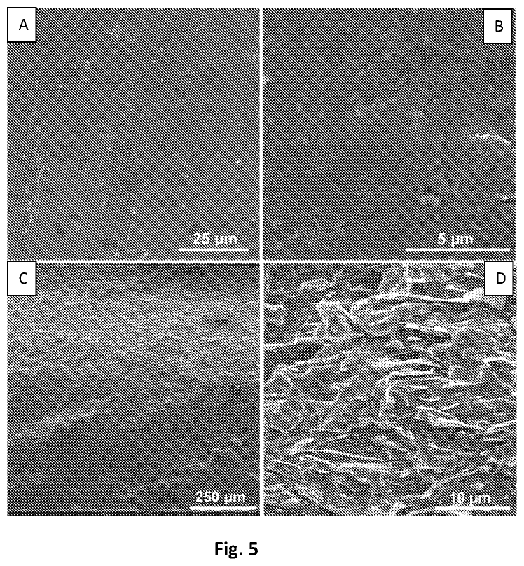

In an embodiment, FIG. 5 shows four scanning electron microscope images of the surface (top left (A) and top right (B)) and cross-section (bottom left (C) and bottom right (D)) of the present disclosure. It is possible to observe that there is no formation of particle agglomerates, and a uniform dispersion can be achieved, validating the synergy between the graphene platelets and carbon black. From the cross-section images (C and D) a homogeneous particle dispersion is also observed along the entirety of the slab thickness, with the graphene platelets being mostly oriented in the same direction.

The term “comprising” whenever used in this document is intended to indicate the presence of stated features, integers, steps, components, but not to preclude the presence or addition of one or more other features, integers, steps, components, or groups thereof.

The disclosure should not be seen in any way restricted to the embodiments described and a person with ordinary skill in the art will foresee many possibilities to modifications thereof. The above-described embodiments are combinable.

The following claims further set out particular embodiments of the disclosure.

1. An electromagnetic wave shielding thermoplastic composition, comprising:
0.1 to 50 wt. % of graphene as a first carbon-based conductive material;
0.1 to 25 wt. % of a further carbon-based conductive material;
10 to 90 wt. % of a polymer matrix;
wherein the weight ratio of graphene to the further carbon-based conductive material (wt/wt) ranges from 3:1 to 2:1;
wherein the further carbon-based conductive material is crystalline or semicrystalline.

2. A composition according to claim 1, wherein the weight ratio of graphene to the further carbon-based conductive material (wt/wt) is 2.5:1 to 2:1.

3. A composition according to claim 1, wherein the weight ratio of graphene to the further carbon-based conductive material (wt/wt) is 2:1.

4. A composition according to claim 1, wherein the further carbon-based conductive material is a material comprising carbon-based particles and/or is nanostructured.

5. A composition according to claim 1, wherein the further carbon-based conductive material is selected from the list:
natural and synthetic graphite, carbon black, carbon nanotubes, carbon fibers, carbon nano onions, graphene oxide, carbon nanospheres, fullerenes, or mixtures thereof.

6. A composition according to claim 5, wherein the further carbon-based conductive material is carbon black.

7. A composition according to claim 1, wherein the graphene lateral size is from 0.5 to 30 μm.

8. A composition according to claim 1, wherein the graphene is in the form of platelets or nanoplatelets particle lateral size ranges from 1.5 to 5 μm.

9. A composition according to claim 1, wherein the amount of graphene is 1 to 30 wt. %.

10. A composition according to claim 1, wherein the graphene is functionalized with ferromagnetic particles.

11. A composition according to the claim 10, the graphene is functionalized with ferromagnetic particles up to 75 wt. % of the graphene is functionalized with ferromagnetic particles.

12. A composition according to claim 10, wherein the ferromagnetic particles are iron oxide.

13. A composition according to claim 1, wherein the amount of further carbon-based conductive material ranges from 0.3 to 20 wt. %.

14. A composition according to claim 1, wherein the polymer matrix is selected from the list: polyvinyl chloride, polyamide, polybutylene terephthalate, cross-linked polyethylene, fluorinated ethylene propylene, polyethylene, polypropylene, polystyrene, acrylonitrile butadiene styrene, polylactic acid, polytetrafluoroethylene, polyethylene terephthalate, polymethylmethacrylate, thermoplastic elastomer, thermoplastic polyurethane, polychlorotrifluoroethylene, polyacrylonitrile, polycarbonate, polydimethylsiloxane, polyethersulfone, polysulfone, polyether ether ketone, polyphenylene sulfide, polyamideimide, and polyetherimide, or mixtures thereof.

15. A composition according to claim 1, wherein the polymer matrix is polypropylene, polyvinyl chloride or polyamide or polybutylene terephthalate, or acrylonitrile butadiene styrene or polyethylene.

16. A composition according to claim 1, further comprising 0.1 to 25 wt. % of an additive selected from a plasticizer, a dispersant, an antioxidant, or combinations thereof.

17. A composition according to claim 16, wherein the additive is a plasticizer selected from the list: phthalate esters, trimellitate, aliphatic dibasic acid esters, benzoate esters, polyesters, citrates, epoxidized soybean oil, epoxidized linseed oil (ELO), castor oil, palm oil, starches, sugars, phosphates, chlorinated paraffins, alkyl sulfonic acid esters, or their mixtures thereof.

18. A composition according to claim 1, further comprising ferromagnetic particles.

19. An electromagnetic wave shielding thermoplastic granulate, thermoplastic powder, thermoplastic film, thermoplastic sheet or thermoplastic paste comprising the composition according to claim 1.

20. A method of electromagnetic wave shielding comprising applying a composition as a shielding part of industrial equipment, electronic parts, medical devices, communication devices, office devices, military devices, automotive components, aerospace devices, EMI/RFI shielding enclosures, automobile cables, solar panels, consumer electronics, mobile and flexible electronics, wearable electronics, board-level shielding and patches,
wherein said composition comprises:
0.1 to 50 wt. % of graphene as a first carbon-based conductive material;
0.1 to 25 wt. % of a further carbon-based conductive material;
10 to 90 wt. % of a polymer matrix;
wherein the weight ratio of graphene to the further carbon-based conductive material (wt/wt) ranges from 3:1 to 1:0.5.
